(19) United States
(12) Patent Application Publication
(10) Pub. No.: US 2013/0026609 A1
(43) Pub. Date: Jan. 31, 2013

(54) PACKAGE ASSEMBLY INCLUDING A SEMICONDUCTOR SUBSTRATE WITH STRESS RELIEF STRUCTURE

(71) Applicant: Marvell World Trade Ltd., St. Michael (BB)

(72) Inventors: Albert Wu, Palo Alto, CA (US); Chien-Chuan (David) Wei, Los Gatos, CA (US)

(73) Assignee: MARVELL WORLD TRADE LTD., St. Michael (BB)

(21) Appl. No.: 13/648,114

(22) Filed: Oct. 9, 2012

Related U.S. Application Data
(63) Continuation-in-part of application No. 12/973,249, filed on Dec. 20, 2010.
(60) Provisional application No. 61/295,925, filed on Jan. 18, 2010.
(60) Provisional application No. 61/328,556, filed on Apr. 27, 2010.
(60) Provisional application No. 61/333,542, filed on May 11, 2010.
(60) Provisional application No. 61/347,156, filed on May 21, 2010.
(60) Provisional application No. 61/350,852, filed on Jun. 2, 2010.
(60) Provisional application No. 61/545,549, filed on Oct. 10, 2011.

(51) Int. Cl. H01L 23/488; H01L 21/58

(52) U.S. Cl. 257/632; 438/108; 257/E21.505; 257/E23.023

(57) ABSTRACT

An apparatus configured to be coupled onto a substrate, wherein the apparatus comprises a semiconductor substrate and the semiconductor substrate includes a plurality of trenches defined within a side of the semiconductor substrate. The apparatus further comprises an interconnect layer over portions of the side of the semiconductor substrate, wherein the portions of the side of the semiconductor substrate include the plurality of trenches defined within the side of the semiconductor substrate. Each trench is configured to respectively receive a solder ball to provide an interface between i) the interconnect layer and ii) the substrate to which the apparatus is to be coupled.

### CROSS REFERENCE TO RELATED APPLICATIONS

This disclosure is a continuation-in-part of and claims priority to U.S. patent application Ser. No. 12/973,249, filed on Dec. 20, 2010, which claims priority to U.S. Provisional Patent Application No. 61/295,925, filed on Jan. 18, 2010; U.S. Provisional Patent Application No. 61/328,556, filed on Apr. 27, 2010; U.S. Provisional Patent Application No. 61/333,542, filed on May 11, 2010; U.S. Provisional Patent Application No. 61/347,156, filed on May 21, 2010; and U.S. Provisional Patent Application No. 61/350,852, filed on Jun. 2, 2010. This disclosure further claims priority to U.S. Provisional Patent Application No. 61/545,549, filed on Oct. 10, 2011.

The present disclosure is related to U.S. patent application Ser. No. 13/012,644, filed on Jan. 24, 2011, which claims priority to U.S. Provisional Patent Application No. 61/301,125, filed on Feb. 3, 2010; U.S. Provisional Patent Application No. 61/316,282, filed on Mar. 22, 2010; U.S. Provisional Patent Application No. 61/321,068, filed on Apr. 5, 2010; and U.S. Provisional Patent Application No. 61/325,189, filed on Apr. 16, 2010. The disclosures of the foregoing applications referenced in this section are incorporated herein by reference.

### TECHNICAL FIELD

Embodiments of the present disclosure relate to the field of integrated circuits, and more particularly, to techniques, structures, and configurations of semiconductor substrates for package assemblies.

### BACKGROUND

The background description provided herein is for the purpose of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

Integrated circuit devices, such as transistors, are formed on semiconductor dies that continue to scale in size to smaller dimensions. The shrinking dimensions of semiconductor dies are challenging conventional substrate fabrication and/or package assembly technologies and configurations that are currently used to route electrical signals to or from a semiconductor die. For example, laminate substrate technologies may not produce sufficiently small features on a substrate to correspond with the finer pitches of interconnects or other signal-routing features formed on semiconductor dies.

Furthermore, with the decreasing size of semiconductor dies, and thereby the packaging assemblies that include the semiconductor dies, interfaces attaching such packaging assemblies to substrates, such as printed circuit boards, can become more fragile. For example, interfaces between such a packaging assembly and the printed circuit board can be compromised due to stress suffered from the thermal temperature cycle of the packaging assembly. Additionally, when such a packaging assembly and the printed circuit board are dropped, the interface can suffer to the point of breaking.

### SUMMARY

In one embodiment, the present disclosure provides an apparatus configured to be coupled onto a substrate, wherein the apparatus comprises a semiconductor substrate and the semiconductor substrate includes a plurality of trenches defined within a side of the semiconductor substrate. The apparatus further comprises an interconnect layer over portions of the side of the semiconductor substrate, wherein the portions of the side of the semiconductor substrate include the plurality of trenches defined within the side of the semiconductor substrate. Each trench is configured to respectively receive a solder ball to provide an interface between i) the interconnect layer and ii) the substrate to which the apparatus is to be coupled.

In another embodiment, the present disclosure provides a method comprising providing a semiconductor substrate defining a plurality of trenches within a side of the semiconductor substrate, and forming an interconnect layer on the side of the semiconductor substrate. The interconnect layer is over at least portions of the side of the semiconductor substrate that include the plurality of trenches defined within the side of the semiconductor substrate. Each trench is configured to respectively receive a solder ball to provide an interface between i) the interconnect layer and ii) a substrate to which the semiconductor substrate is to be coupled.

### BRIEF DESCRIPTION OF THE DRAWINGS

Embodiments of the present disclosure will be readily understood by the following detailed description in conjunction with the accompanying drawings. To facilitate this description, like reference numerals designate like structural elements. Embodiments herein are illustrated by way of example and not by way of limitation in the figures of the accompanying drawings.

FIG. 1 schematically illustrates an example package assembly using an example of a semiconductor substrate.

FIG. 1A schematically illustrates an example package assembly using another example of a semiconductor substrate.

FIG. 1B schematically illustrates an example package assembly using another example of a semiconductor substrate.

FIGS. 2A-2C schematically illustrates the semiconductor substrate of FIG. 1 subsequent to various process operations.

FIGS. 2D- 2J schematically illustrate the semiconductor substrate of FIGS. 1A and 1B subsequent to various process operations.

FIGS. 3A-3D schematically illustrates a package assembly using a semiconductor substrate subsequent to various process operations.

FIGS. 4A-4B schematically illustrate the package assembly of FIG. 3B subsequent to various process operations.

FIGS. 5A-5G schematically illustrate the package assembly of FIG. 3A subsequent to various process operations.

FIGS. 6-11 schematically illustrate various package assembly configurations using a semiconductor substrate.

FIG. 12 is a process flow diagram of a method to fabricate a package assembly using a semiconductor substrate.

FIG. 13 is a process flow diagram of another method to fabricate a package assembly using a semiconductor substrate.

FIG. 14 is a process flow diagram of yet another method to fabricate a package assembly using a semiconductor substrate.

FIG. 15 is a process flow diagram of a method to fabricate the semiconductor substrates of FIGS. 1A and 1B.

### DETAILED DESCRIPTION

Embodiments of the present disclosure describe techniques, structures, and configurations for integrated circuit (IC) package assemblies (referred to as “package assemblies” herein) using semiconductor substrates. In the following detailed description, reference is made to the accompanying drawings which form a part hereof, wherein like numerals designate like parts throughout. Other embodiments may be utilized and structural or logical changes may be made without departing from the scope of the present disclosure. Therefore, the following detailed description is not to be taken in a limiting sense, and the scope of embodiments is defined by the appended claims and their equivalents.

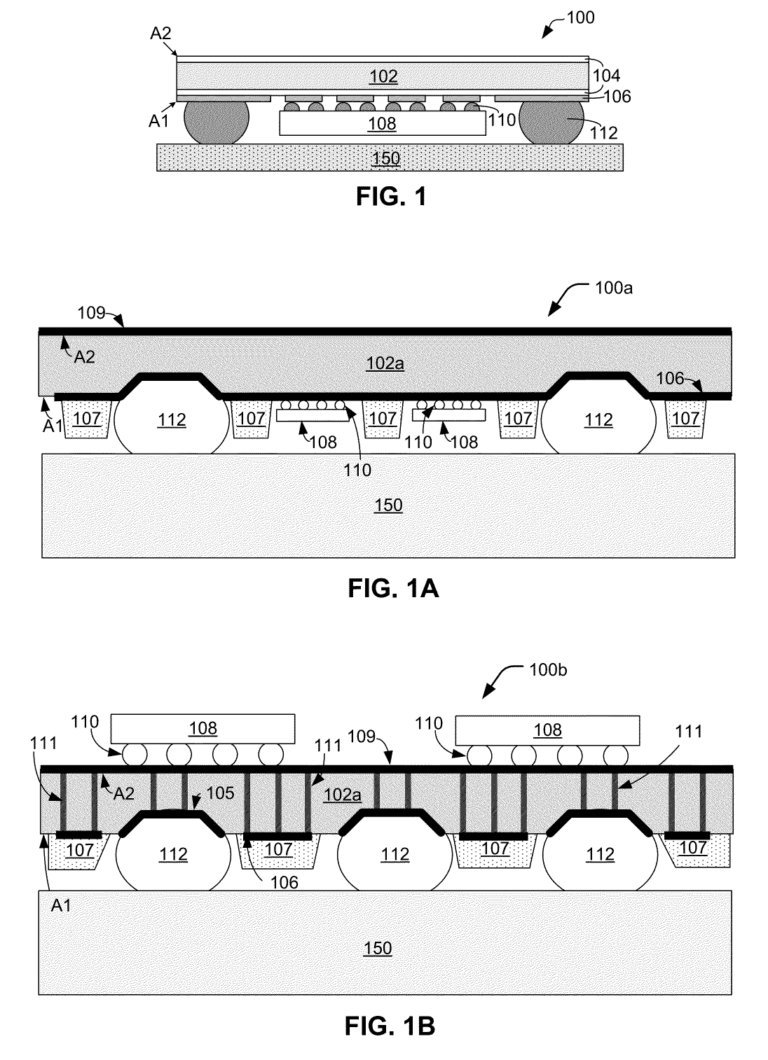

FIG. 1 schematically illustrates an example package assembly 100 including a semiconductor substrate 102. As used herein, the semiconductor substrate 102 refers to a substrate or interposer that substantially comprises a semiconductor material such as, for example, silicon (Si). That is, the bulk of the material of the semiconductor substrate is a semiconductor material. The semiconductor material can include crystalline and/or amorphous types of material. In the case of silicon, for example, the silicon can include single crystal and/or polysilicon types. In other embodiments, the semiconductor substrate 102 can include other semiconductor materials such as, for example, germanium, group III-V materials, or group II-VI materials, that can also benefit from the principles described herein.

Generally, the semiconductor substrate 102 is fabricated using technologies similar to those that are used to fabricate IC structures on a semiconductor die or chip (e.g., one or more semiconductor dies 108). For example, well-known patterning processes (e.g., lithography and/or etch) and deposition processes for fabricating IC devices on a semiconductor die can be used to form structures on the semiconductor substrate 102. By using semiconductor fabrication techniques, the semiconductor substrate 102 can include smaller features than other types of substrates such as laminate (e.g., organic) substrates. The semiconductor substrate 102 may facilitate routing of electrical signals for current semiconductor dies, which continue to shrink in size. For example, in some embodiments, the semiconductor substrate 102 allows for fine pitch Si-to-Si interconnects and final line routing between the semiconductor substrate 102 and the one or more semiconductor dies 108.

The semiconductor substrate 102 includes a first side, A1, and a second side, A2, that is disposed opposite to the first side A1. The first side A1 and the second side A2 generally refer to opposing surfaces of the semiconductor substrate 102 to facilitate the description of various configurations described herein and are not intended to be limited to a particular structure of the semiconductor substrate 102.

A dielectric layer 104 is formed on at least the first side A1 of the semiconductor substrate 102 and can also be formed on the second side A2 of the semiconductor substrate 102. The dielectric layer 104 can be formed by depositing an electrically insulative material such as, for example, silicon dioxide (SiO₂), silicon nitride (SiN), or silicon oxynitride (SiOₓN_{y}), where x and y represent suitable stoichiometric values, to substantially cover one or more surfaces of the semiconductor substrate 102, as shown. Other suitable electrically insulative materials can be used in other embodiments. The dielectric layer 104 can be formed by using a deposition technique including, for example, physical vapor deposition (PVD), chemical vapor deposition (CVD), and/or atomic layer deposition (ALD). Other suitable deposition techniques can be used in other embodiments.

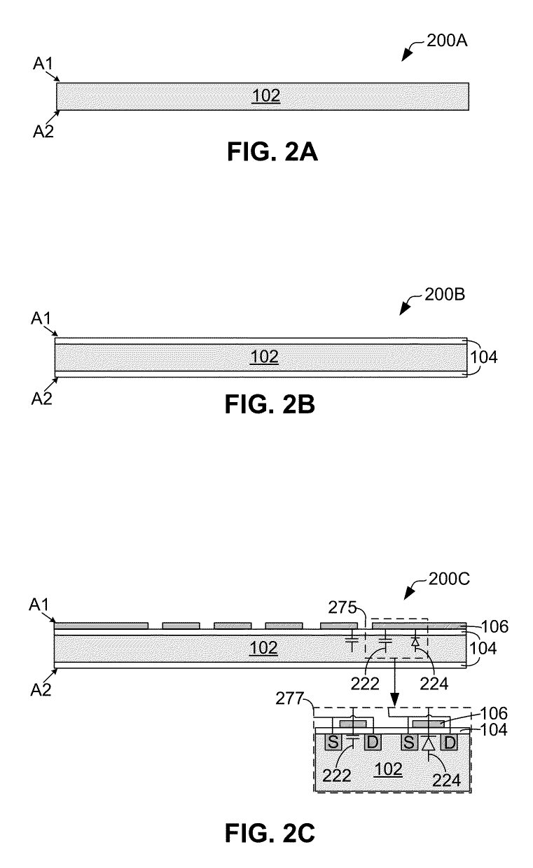

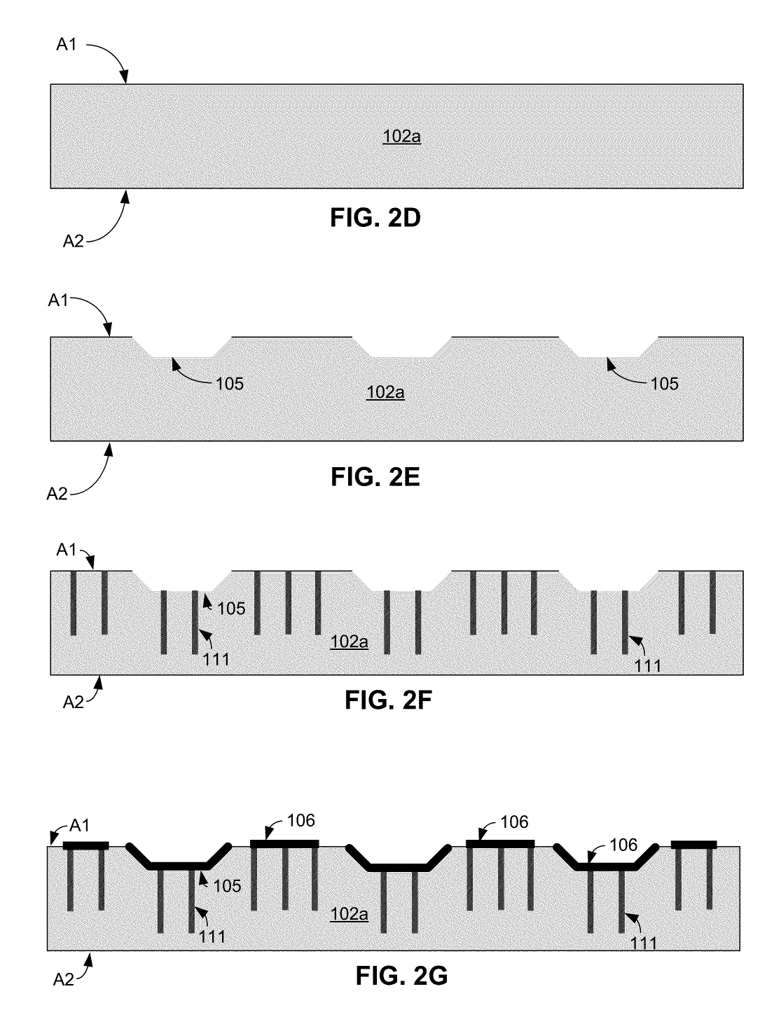

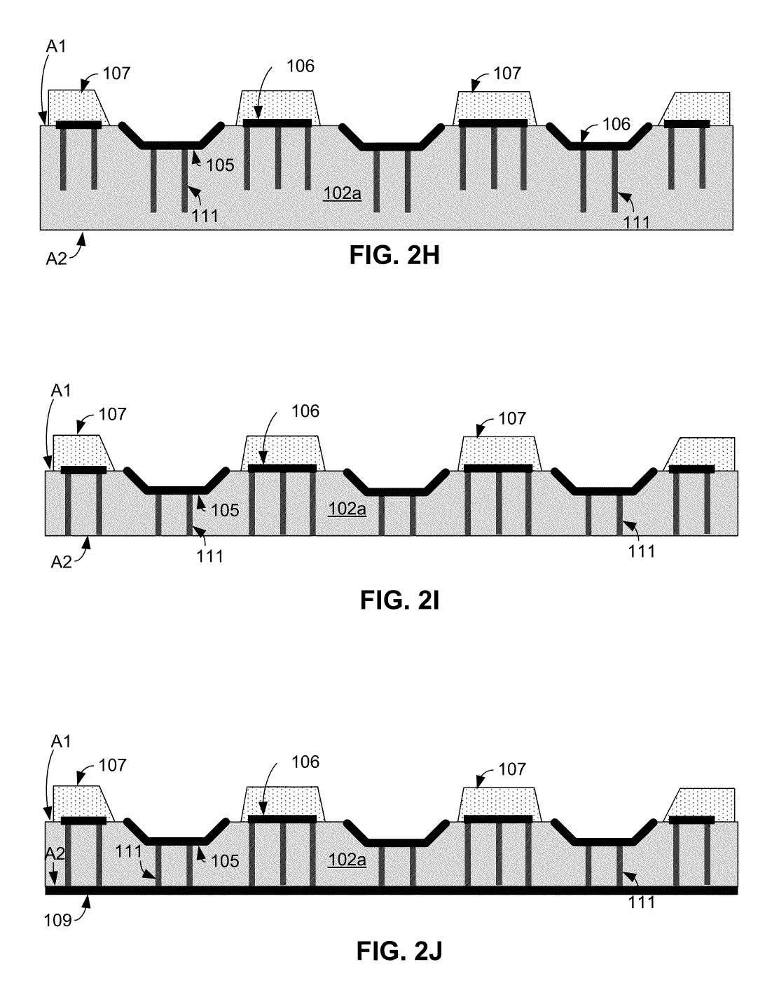

The dielectric layer 104 can provide electrical isolation for features formed on the semiconductor substrate 102. For example, the dielectric layer 104 can be used to prevent shorting between electrically conductive features (e.g., one or more interconnect layers 106) formed on the dielectric layer 104 and the semiconductor material (e.g., silicon) of the semiconductor substrate 102. The dielectric layer 104 can further be used as a gate dielectric in the formation of one or more devices (e.g., capacitor 222 of FIG. 2C) on the semiconductor substrate 102.

One or more interconnect or redistribution layers 106 are formed on the dielectric layer 104 to route electrical signals such as, for example, input/output (I/O) signals and/or power/ground signals, to and/or from one or more semiconductor dies 108 coupled to the semiconductor substrate 102. The one or more interconnect layers 106 can be formed by depositing and/or patterning an electrically conductive material such as, for example, a metal (e.g., copper or aluminum) or a doped semiconductor material (e.g., doped polysilicon). Other suitable electrically conductive materials can be used in other embodiments. The one or more interconnect layers 106 can include a variety of structures to route the electrical signals such as, for example, pads, lands, or traces. Although not depicted, a passivation layer comprising an electrically insulative material such as, for example, polyimide can be deposited on the one or more interconnect layers 106 and patterned to provide openings in the passivation layer to facilitate electrical coupling of the one or more semiconductor dies 108 to the one or more interconnect layers 106.

The one or more semiconductor dies 108 are attached to the first side A1 of the semiconductor substrate 102 using any suitable configuration including, for example, a flip-chip configuration, as depicted. Other suitable die-attach configurations such as, for example, a wire-bonding configuration can be used in other embodiments.

In the depicted embodiment, one or more bumps 110 are formed on the one or more semiconductor dies 108 and bonded to the one or more interconnect layers 106. The one or more bumps 110 generally comprise an electrically conductive material such as, for example, solder or other metal to route the electrical signals of the one or more semiconductor dies 108. According to various embodiments, the one or more bumps 110 comprise lead, gold, tin, copper, or lead-free materials, or combinations thereof. The one or more bumps 110 can have a variety of shapes including spherical, cylindrical, rectangular, or other shapes and can be formed using a bumping process, such as, for example, a controlled collapse chip connect (C4) process, stud-bumping, or other suitable bumping process.

The one or more bumps 110 can be formed on the one or more semiconductor dies 108 while the one or more semiconductor dies 108 are in either wafer or singulated form. The one or more semiconductor dies 108 can be attached to the semiconductor substrate 102 while the semiconductor substrate 102 is in either wafer or singulated form.

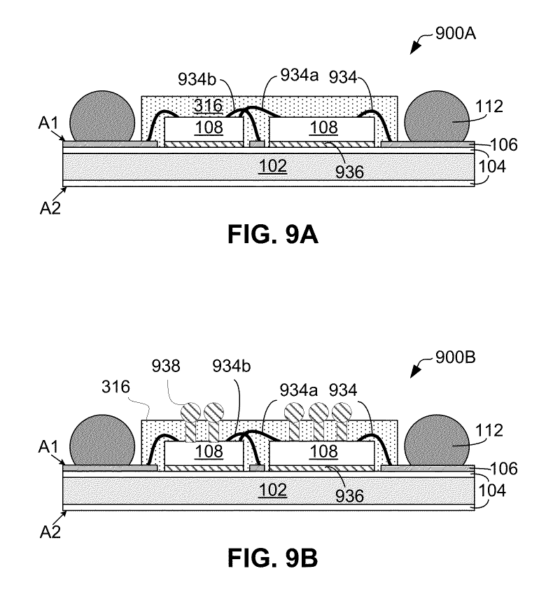

The one or more semiconductor dies 108 generally have an active side that includes a surface upon which a plurality of integrated circuit (IC) devices (not shown) such as transistors for logic and/or memory are formed and an inactive side that is disposed opposite to the active side. The active side of the one or more semiconductor dies 108 is electrically coupled to the one or more interconnect layers 106. In the depicted embodiment, the active side of the one or more semiconductor dies 108 is coupled to the one or more interconnect layers 106 using the one or more bumps 110. In other embodiments, the active side of the one or more semiconductor dies 108 is electrically coupled to the one or more interconnect layers 106 using other structures, such as, for example, one or more bonding wires (e.g., one or more bonding wires 934 of FIG. 9).

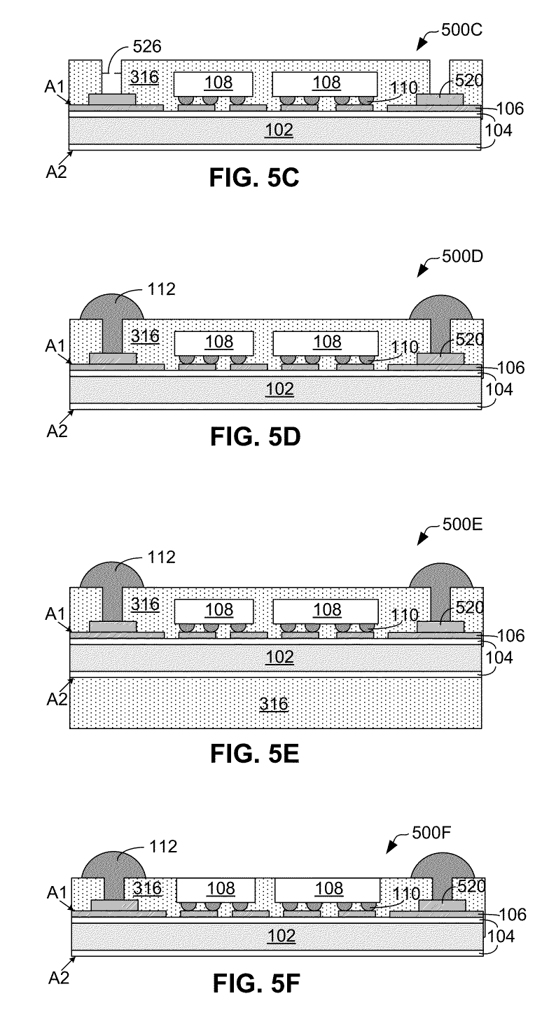

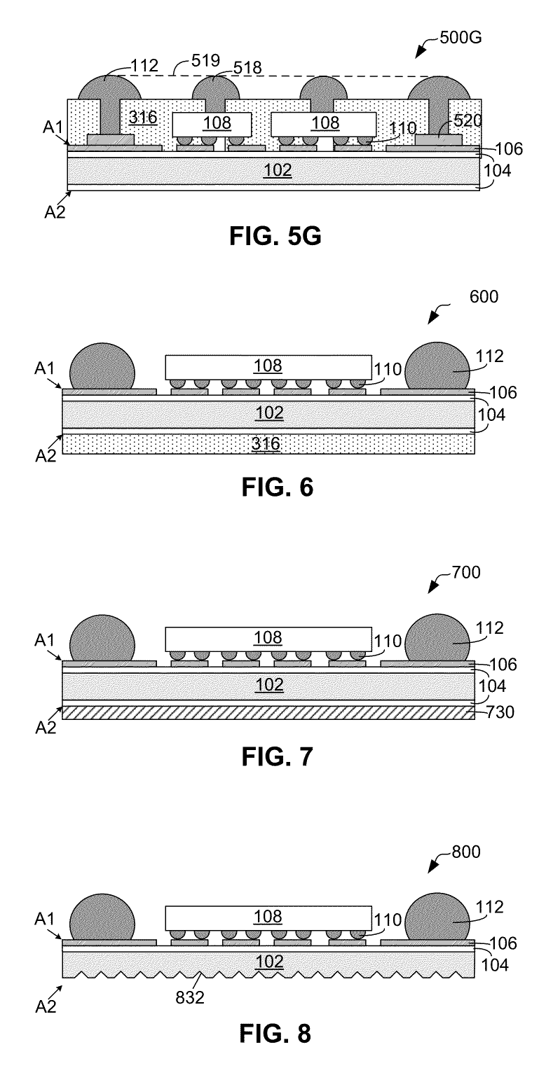

One or more package interconnect structures such as, for example, one or more solder balls 112 or bumps (e.g., the one or more bumps 520 of FIG. 5A) can be formed on the one or more interconnect layers 106 to further route the electrical signals of the one or more semiconductor dies 108. The one or more package interconnect structures generally comprise an electrically conductive material. In some embodiments, the one or more package interconnect structures are disposed adjacent to a peripheral portion of the semiconductor substrate 102 and the one or more semiconductor dies 108 are disposed adjacent to a central portion of the semiconductor substrate 102, as depicted. The one or more package interconnect structures can be formed in a variety of shapes including spherical, planar, polygon, or combinations thereof.

According to various embodiments, the one or more semiconductor dies 108 and the semiconductor substrate 102 are coupled together to form the package assembly 100. The package assembly 100 can be electrically coupled to other electrical devices such as a printed circuit board (PCB) 150 (e.g., motherboard), another package, a semiconductor die, or a module using the one or more package interconnect structures to further route the electrical signals of the one or more semiconductor dies 108. The one or more package interconnect structures (e.g., the one or more solder balls 112) can be sized, in some embodiments, to provide a gap between the one or more semiconductor dies 108 and the printed circuit board 150, as shown.

FIGS. 1A and 1B illustrate another example of package assemblies 100a and 100b that include a semiconductor substrate 102a. The semiconductor substrate 102a is similar to the semiconductor substrate 102. However, the semiconductor substrate 102a includes recessed trenches 105 that are configured to receive solder balls 112. Additionally, in the example package assembly 100a, two semiconductor dies 108 are included.

As with semiconductor substrate 102, the semiconductor substrate 102a refers to a substrate or interposer that substantially comprises a semiconductor material such as, for example, silicon (Si). That is, the bulk of the material of the semiconductor substrate is a semiconductor material. The semiconductor material can include crystalline and/or amorphous types of material. In the case of silicon, for example, the silicon can include single crystal and/or polysilicon types. In other embodiments, the semiconductor substrate 102a can include other semiconductor materials such as, for example, germanium, group III-V materials, or group II-VI materials, that can also benefit from the principles described herein.

Generally, the semiconductor substrate 102a is fabricated using technologies similar to those that are used to fabricate IC structures on a semiconductor die or chip (e.g., one or more semiconductor dies 108). For example, well-known patterning processes (e.g., lithography and/or etch) and deposition processes for fabricating IC devices on a semiconductor die can be used to form structures on the semiconductor substrate 102a. By using semiconductor fabrication techniques, the semiconductor substrate 102a can include smaller features than other types of substrates such as laminate (e.g., organic) substrates. The semiconductor substrate 102a may facilitate routing of electrical signals for current semiconductor dies, which continue to shrink in size. For example, in some embodiments, the semiconductor substrate 102a allows for fine pitch Si-to-Si interconnects and final line routing between the semiconductor substrate 102a and the one or more semiconductor dies 108.

The semiconductor substrate 102a includes a first side, A1, and a second side, A2, that is disposed opposite to the first side A1. The first side A1 and the second side A2 generally refer to opposing surfaces of the semiconductor substrate 102a to facilitate the description of various configurations described herein and are not intended to be limited to a particular structure of the semiconductor substrate 102a.

Multiple trenches 105 are defined within the semiconductor substrate 102a by etching the semiconductor substrate 102a. The trenches 105 are configured to receive solder balls 112.

One or more interconnect or redistribution layers 106 are formed on the semiconductor substrate 102a to cover at least portions of the first side A1 of the semiconductor substrate 102a. The portions covered by the interconnect layers 106 include at least the trenches 105. The redistribution layers 106 are used to route electrical signals such as, for example, input/output (I/O) signals and/or power/ground signals, to and/or from one or more semiconductor dies 108 coupled to the semiconductor substrate 102a. The one or more interconnect layers 106 can be formed by depositing and/or patterning an electrically conductive material such as, for example, a metal (e.g., copper or aluminum) or a doped semiconductor material (e.g., doped polysilicon). Other suitable electrically conductive materials can be used in other embodiments. The one or more interconnect layers 106 can include a variety of structures to route the electrical signals such as, for example, pads, lands, or traces. The one or more interconnect layers 106 can be a single, continuous layer, as illustrated in FIG. 1A, if desired, or can be in multiple sections or portions, as illustrated in FIG. 1B, if desired.

A passivation layer 107 comprising an electrically insulative material such as, for example, polyimide can be deposited on the one or more interconnect layers 106 and patterned to provide openings in the passivation layer to facilitate electrical coupling of the one or more semiconductor dies 108 to the one or more interconnect layers 106. The passivation layer 107 is similar to dielectric layer 104 of FIG. 1 and can be formed by depositing and patterning an electrically insulative material such as, for example, silicon dioxide (SiO₂), silicon nitride (SiN), or silicon oxynitride (SiOₓN_{y}), where x and y represent suitable stoichiometric values, to substantially cover one or more surfaces of the semiconductor substrate 102a. Other suitable electrically insulative materials can be used in other embodiments.

Such a passivation layer 107 can provide electrical isolation for features formed on the semiconductor substrate 102a. For example, the passivation layer 107 can be used to prevent shorting between electrically conductive features (e.g., one or more interconnect layers 106) formed on or within the semiconductor material (e.g., silicon) of the semiconductor substrate 102. The passivation layer 107 can further be used as a gate dielectric in the formation of one or more devices (e.g., capacitor 222 of FIG. 2C) on the semiconductor substrate 102a.

In FIG. 1A, the one or more semiconductor dies 108 of package assembly 100a are attached to the first side A1 of the semiconductor substrate 102a using any suitable configuration including, for example, a flip-chip configuration, as depicted. Other suitable die-attach configurations such as, for example, a wire-bonding configuration can be used in other embodiments. In FIG. 1B, the one or more semiconductor dies 108 of package assembly 100b are attached to the second side A2 of the semiconductor substrate 102a using any suitable configuration including, for example, a flip-chip configuration, as depicted. Other suitable die-attach configurations such as, for example, a wire-bonding configuration can be used in other embodiments.

In the embodiments of FIGS. 1A and 1B, one or more bumps 110 are formed on the one or more semiconductor dies 108 and bonded to the one or more interconnect layers 106. The one or more bumps 110 generally comprise an electrically conductive material such as, for example, solder or other metal to route the electrical signals of the one or more semiconductor dies 108. According to various embodiments, the one or more bumps 110 comprise lead, gold, tin, copper, or lead-free materials, or combinations thereof. The one or more bumps 110 can have a variety of shapes including spherical, cylindrical, rectangular, or other shapes and can be formed using a bumping process, such as, for example, a controlled collapse chip connect (C4) process, stud-bumping, or other suitable bumping process.

The one or more bumps 110 can be formed on the one or more semiconductor dies 108 while the one or more semiconductor dies 108 are in either wafer or singulated form. The one or more semiconductor dies 108 can be attached to the semiconductor substrate 102a while the semiconductor substrate 102a is in either wafer or singulated form.

The one or more semiconductor dies 108 generally have an active side that includes a surface upon which a plurality of integrated circuit (IC) devices (not shown) such as transistors for logic and/or memory are formed and an inactive side that is disposed opposite to the active side. The active side of the one or more semiconductor dies 108 is electrically coupled to the one or more interconnect layers 106 in the package assembly 100a and interconnect layer 109 in the package assembly 100b. In the depicted embodiments, the active side of the one or more semiconductor dies 108 is coupled to the one or more interconnect layers 106 or 109 using the one or more bumps 110. In other embodiments, the active side of the one or more semiconductor dies 108 is electrically coupled to the one or more interconnect layers 106 or 109 using other structures, such as, for example, one or more bonding wires (e.g., one or more bonding wires 934 of FIG. 9).

One or more package interconnect structures such as, for example, one or more solder balls 112 or bumps can be formed on the one or more interconnect layers 106 within the trenches 105 to further route the electrical signals of the one or more semiconductor dies 108. The one or more package interconnect structures 112 generally comprise an electrically conductive material. In some embodiments, the one or more package interconnect structures 112 are disposed adjacent to a peripheral portion of the semiconductor substrate 102a and the one or more semiconductor dies 108 are disposed adjacent to a central portion of the semiconductor substrate 102a, as depicted. The one or more package interconnect structures 112 can be formed in a variety of shapes including spherical, planar, polygon, or combinations thereof.

According to various embodiments, the one or more semiconductor dies 108 and the semiconductor substrate 102a are coupled together to form the package assemblies 100a, 100b. The package assemblies 100a, 100b can be electrically coupled to other substrates or electrical devices such as a printed circuit board (PCB) 150 (e.g., motherboard), another package assembly, a semiconductor die, or a module using the one or more solder balls 112 to further route the electrical signals of the one or more semiconductor dies 108. The one or more package interconnect structures (e.g., the one or more solder balls 112) can be sized, in some embodiments, to provide a gap between the one or more semiconductor dies 108 and the printed circuit board 150, as shown.

The recessed trenches for the solder balls 112 increase the solder contact area between the solder balls 112 and the semiconductor substrate 102a. The increased solder contact area provides greater support for the silicon substrate 102a, which allows for better stress endurance when the package assembly 100a or 100b goes through a temperature cycle during operation. The increased solder contact area also provides better stress endurance if a device including the package assembly 100a or 100b is dropped. Thus, the interface between the redistribution layer 106 of the semiconductor substrate 102a and the solder balls 112 is strengthened, thereby strengthening the interface between the packaging assembly 100a or 100b and the printed circuit board 150.

As can be seen in FIG. 1B, through-silicon vias 111 can be included within silicon substrate 102a. The through-silicon vias 111 can allow for electrical coupling of the two redistribution layers 106, 109 as well as components on or within the silicon substrate 102a. Additionally, the through-silicon vias 111 can allow for electrical coupling of components, such as semiconductor dies 108 located on side A1 and/or A2 of the semiconductor substrate 102a and the printed circuit board 150. The through-silicon vias 111 can also allow for electrical coupling of semiconductor dies 108 located on side A1 and/or A2 of the semiconductor substrate 102a with other components on or within the silicon substrate 102a.

FIGS. 2A-2C schematically illustrates the semiconductor substrate 102 subsequent to various process operations. Referring to FIG. 2A, a semiconductor substrate 102 comprising a semiconductor material is depicted. The semiconductor substrate 102 can include, for example, opposing planar surfaces on the first side A1 and the second side A2. The semiconductor substrate 102 can be cut, for example, from an ingot of monocrystalline or polycrystalline semiconductor material. The semiconductor substrate 102 is generally in wafer form during processing described in connection with FIGS. 2A-2C, but can be in singulated form.

Referring to FIG. 2B, the semiconductor substrate 102 is depicted subsequent to formation of a dielectric layer 104 on at least the first side A1 of the semiconductor substrate 102. The dielectric layer 104 can be formed on the second side A2 in addition to the first side A1 in some embodiments.

Referring to FIG. 2C, the semiconductor substrate 102 is depicted subsequent to formation of one or more interconnect layers 106 on the dielectric layer 104 that is disposed on the first side A1 of the semiconductor substrate 102. A passivation layer (not shown) can be deposited on the one or more interconnect layers 106 and patterned to provide openings for electrically coupling one or more semiconductor dies (e.g., the one or more semiconductor dies 108 of FIG. 1) to the one or more interconnect layers 106.

According to various embodiments, one or more devices including IC devices and/or passive devices can be formed on the first side A1 of the semiconductor substrate 102. For example, an example capacitor 222 and an example electro-static discharge (ESD) protection device 224 can be formed on the semiconductor substrate 102 as depicted in region 275 of the semiconductor substrate 102. An enlarged view of region 275 is depicted in region 277, which shows the capacitor 222 and the ESD protection device 224 in greater detail.

The capacitor 222 can be, for example, a de-coupling capacitor to reduce noise associated with the electrical signals such as power/ground signals of the one or more semiconductor dies. The capacitor 222 can include, for example, a metal-oxide-semiconductor (MOS) structure having a source region, S, and a drain region, D, formed in the semiconductor substrate 102. The source region S and the drain region D can be formed, for example, by using a doping or implant process to alter the electrical conductivity of the semiconductor material of the semiconductor substrate 102. In some embodiments, the source region S and/or the drain region D is implanted with a dopant to form an N-type junction in a P-type substrate. A P-type junction in an N-type substrate can be used in other embodiments. According to various embodiments, the source region S and the drain region D are formed prior to forming the dielectric layer 104 of FIG. 2B. The dielectric layer 104 can function as a gate dielectric for the MOS structure with the one or more interconnect layers 106 functioning as a gate electrode of the MOS structure. The gate electrode can include, for example, doped polysilicon or a metal. Other suitable techniques can be used to form a capacitor 222 in the semiconductor substrate 102 in other embodiments.

The ESD protection device 224 can include, for example, a diode to protect against electro-static discharge. The ESD protection device 224 can be formed, for example, by a doping or implant process to create an N-type region in the semiconductor substrate 102, which may be a P-type substrate in some embodiments. A P-type region can be formed in an N-type substrate in other embodiments. The ESD protection device 224 can be formed, for example, using techniques associated with forming MOS or bipolar devices. According to various embodiments, the ESD protection device 224 includes a complementary MOS (CMOS), bipolar, transient voltage suppression (TVS) and/or Zener diode or a metal oxide varistor (MOV). The ESD protection device 224 can include other suitable devices that protect against electro-static discharge in other embodiments.

FIGS. 2D-2L schematically illustrate the semiconductor substrate 102a subsequent to various process operations. The silicon substrate 102a can be created in a manner similar to the silicon substrate 102. Referring to FIGS. 2D and 2E, a silicon substrate or interposer 102a is provided. A pattern is provided on the silicon substrate 102a to define locations for the trenches 105 within the silicon substrate 102a. An etching process can be used to create the trenches 105 within the semiconductor substrate 102a, based upon the pattern, in order to define the trenches within the silicon substrate 102a.

Referring to FIG. 2F, if desired, through-silicon vias 111 can be created within the silicon substrate 102a. The through-silicon vias 111 can be created by providing a pattern and then etching the silicon substrate 102a.

Referring to FIG. 2G, the one or more interconnect layers 106 are then formed by depositing metal (or other conductive material) on the first side A1 of the semiconductor substrate 102a. The locations include the trenches 105. Locations for the interconnect layers 106 may be created utilizing a plating process, a lithographic process or an etching process. The locations include the trenches 105.

Referring to FIG. 2H, the passivation layer 107 is formed over the interconnect layers 106 and is etched to expose the portions of the interconnect layers 106 that are to be used for contact with solder bumps 110.

Referring to FIGS. 2I and 2J, a second interconnect layer 109 may also be provided on the second side A2 of semiconductor substrate 102a. The second interconnect layer 109 may be formed by polishing side A2 of semiconductor substrate 102a in order to expose any through-silicon vias 111 that are included within the silicon substrate 102a, as illustrated in FIG. 2I. The second interconnect layer 109 may then be deposited and formed such that it covers at least any included through-silicon vias 111, as illustrated in FIG. 2J. The second interconnect layer 109 may also be formed such that it provides contact pads that may be needed for solder bumps 110 or any other interconnect structures. The second interconnect layer 109 may be one continuous layer, as illustrated, if desired, can be in multiple sections or portions, if desired.

Dielectric layers (not illustrated) similar to the dielectric layers 104 of the semiconductor substrate 102 of FIGS. 1 and 2A-2C may also be included within semiconductor substrate 102a, if desired. Additionally, as with the semiconductor substrate 102 of FIGS. 1 and 2A-2C, one or more devices (not illustrated) including IC devices and/or passive devices (e.g, capacitor 222 and electro-static discharge protection device 224) can be formed on the first side A1 of the semiconductor substrate 102a.

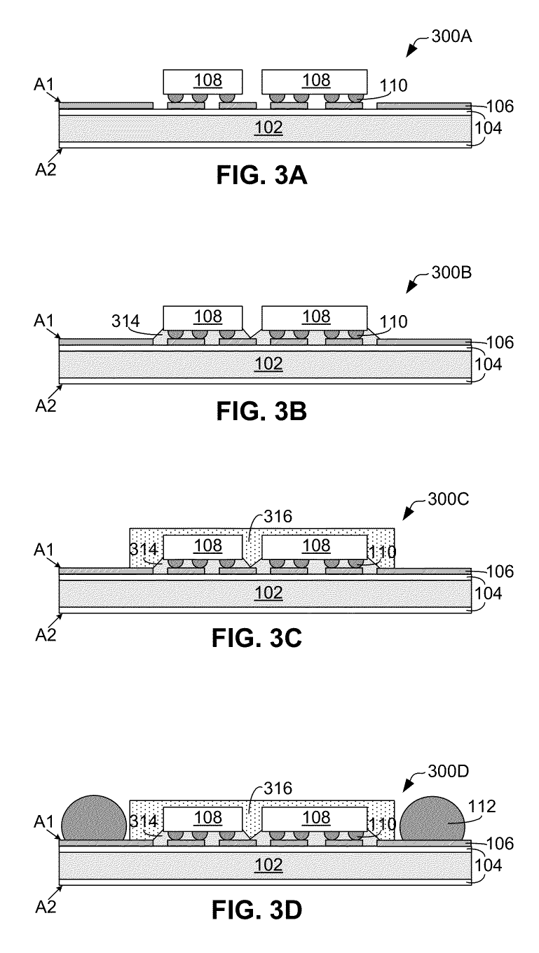

FIGS. 3A-3D schematically illustrates a package assembly using a semiconductor substrate 102 subsequent to various process operations. Although not illustrated, semiconductor substrate 102a may be utilized instead of semiconductor substrate 102.

Referring to FIG. 3A, a package assembly 300A is depicted subsequent to attaching one or more semiconductor dies 108 to the first side A1 of the semiconductor substrate 102 in a flip-chip configuration. In some embodiments, one or more bumps 110 are formed on the active side of the one or more semiconductor dies 108 and subsequently bonded to the one or more interconnect layers 106 to provide an electrical pathway for the electrical signals of the one or more semiconductor dies 108. The one or more semiconductor dies 108 can be attached to the semiconductor substrate 102 when the semiconductor substrate 102 is in either wafer form or singulated form.

Referring to FIG. 3B, a package assembly 300B is depicted subsequent to depositing an underfill material 314 to substantially fill a region between the one or more semiconductor dies 108 and the semiconductor substrate 102. According to various embodiments, the underfill material 314 is deposited in liquid form by a liquid dispensing or injection process. The underfill material 314 can include, for example, an epoxy or other suitable electrically insulative material. The underfill material 314 generally increases adhesion between the one or more semiconductor dies 108 and the semiconductor substrate 102, provides additional electrical insulation between the one or more semiconductor bumps, and/or protects the one or more bumps 110 from moisture and oxidation.

Referring to FIG. 3C, a package assembly 300C is depicted subsequent to depositing a molding compound 316 to substantially encapsulate the one or more semiconductor dies 108. The molding compound 316 generally protects the one or more semiconductor dies 108 from moisture, oxidation, or chipping associated with handling. The molding compound 316 may be used in conjunction with the underfill material 314, as depicted, in cases where the materials used for the molding compound 316 do not readily fill the region (e.g., due to a small pitch of the one or more bumps 110). According to various embodiments, the molding compound 316 is formed by depositing a resin (e.g., a thermosetting resin) in solid form (e.g., a powder) into a mold and applying heat and/or pressure to fuse the resin. In some embodiments, the molding compound 316 is not the same material as the underfill material 314.

Referring to FIG. 3D, a package assembly 300D is depicted subsequent to forming one or more package interconnect structures such as solder balls 112 or bumps on the interconnect layer 106 to further route the electrical signals of the one or more semiconductor dies 108. For example, the solder balls 112 can be printed, electrically plated, or placed on designated locations such as bond pads of the one or more interconnect layers 106. The one or more package interconnect structures can be arranged, for example, in a single row or in multiple rows and can be formed in a variety of locations including a central or a peripheral portion of the package assembly 300D. In some embodiments, the package assembly 300D is a final package assembly. The final package assembly is an assembly that is ready to be mounted on another component such as a printed circuit board (e.g., the printed circuit board 150 of FIG. 1).

When the actions described in connection with FIGS. 3B-3D are performed on a semiconductor substrate 102 in wafer form, the semiconductor substrate 102 is further singulated by a suitable singulation process. According to various embodiments, the semiconductor substrate 102 can be singulated subsequent to the actions described in connection with FIG. 3A, FIG. 3B, FIG. 3C, or FIG. 3D.

In some embodiments, the one or more package interconnect structures (e.g., the one or more solder balls 112) can be formed on the semiconductor substrate 102 of the package assembly 300A to form a final package assembly. The final package assembly using the package assembly 300A may save costs associated with using an underfill material and/or molding compound. In some embodiments, the semiconductor substrate 102 comprises a material that has a coefficient of thermal expansion (CTE) that is substantially the same as a material of the one or more semiconductor dies 108. For example, the semiconductor substrate 102 and the one or more semiconductor dies 108 may both comprise silicon. In such a case, the stress of thermal expansion, which is generally mitigated by the underfill material 314 and/or the molding compound 316, is reduced because the semiconductor substrate 102 and the one or more semiconductor dies 108 have the same CTE. Thus, when the CTE is similar or the same for the semiconductor substrate 102 and the one or more semiconductor dies 108, the underfill material 314 and/or the molding compound 316 may not be used at all.

In some embodiments, the one or more package interconnect structures (e.g., the one or more solder balls 112) can be formed on the semiconductor substrate 102 of the package assembly 300B to form a final package assembly. The final package assembly using the underfill material 314 may increase reliability of joints such as solder joints associated with the one or more bumps 110 of the package assembly 300B.

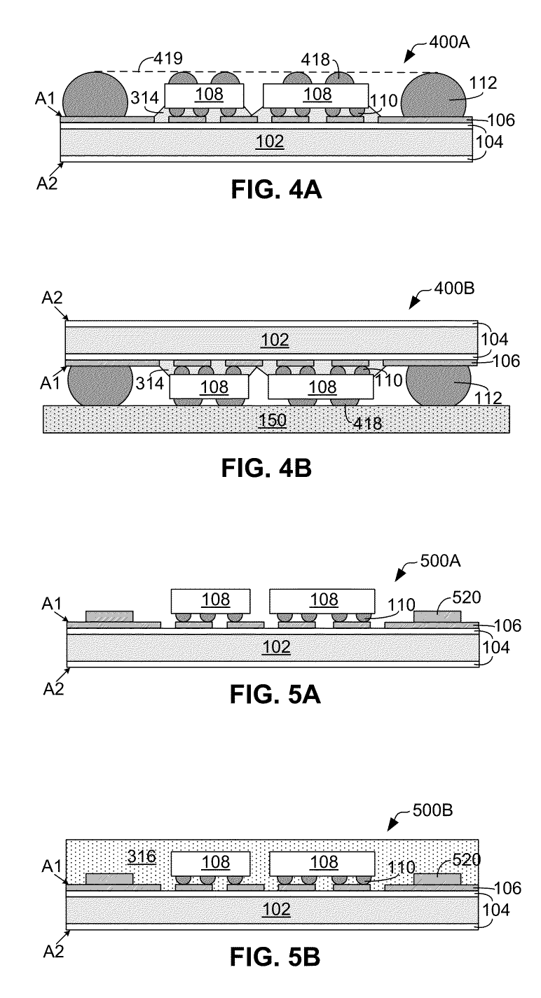

FIGS. 4A-4B schematically illustrate the package assembly 300B of FIG. 3B subsequent to various process operations. Although the package assembly 300B is used as an example to illustrate the principles of these embodiments, the principles can be suitably applied to other package assemblies described herein including, for example, the package assembly 300A. Although not illustrated, semiconductor substrate 102a may be utilized instead of semiconductor substrate 102.

Referring to FIG. 4A, a package assembly 400A is depicted subsequent to the formation of one or more package interconnect structures (e.g., solder balls 112) on the one or more interconnect layers 106 and the formation of one or more thermal dissipation structures (e.g., solder balls 418) on an inactive side of the one or more semiconductor dies 108, as shown. The one or more package interconnect structures and the one or more thermal dissipation structures can include other types of structures such as, for example, bumps in other embodiments. The one or more thermal dissipation structures generally comprise a thermally conductive material such as, for example, metal to provide a thermal path for heat dissipation. The one or more package interconnect structures and the one or more thermal dissipation structures can be sized to have respective surfaces that are substantially coplanar. For example, the solder balls 112 and the solder balls 418 can be sized to have a surface that substantially lies in the same plane 419 to facilitate connection to a substantially planar surface such as a printed circuit board (e.g., printed circuit board 150 of FIG. 4B). In some embodiments, the solder balls 112 are larger in size than the solder balls 418, as depicted.

The actions described in connection with FIG. 4A can be performed when the semiconductor substrate 102 is in either wafer form or singulated form. If in wafer form, the semiconductor substrate 102 is singulated prior to mounting the package assembly 400A on the printed circuit board.

Referring to FIG. 4B, a package assembly 400B is depicted subsequent to attachment of the one or more package interconnect structures (e.g., the one or more solder balls 112) and the one or more thermal dissipation structures (e.g., the one or more solder balls 418) to the printed circuit board 150. According to various embodiments, the package assembly 400B is mounted on the printed circuit board 150 using a surface mount technology (SMT).

FIGS. 5A-5G schematically illustrate the package assembly 300A of FIG. 3A subsequent to various process operations. Although the package assembly 300A is used as an example to illustrate the principles of these embodiments, the principles can be suitably applied to other package assemblies described herein. Although not illustrated, semiconductor substrate 102a may be utilized instead of semiconductor substrate 102.

Referring to FIG. 5A, a package assembly 500A is depicted subsequent to forming one or more package interconnect structures (e.g., one or more bumps 520) on the one or more interconnect layers 106. The one or more bumps 520 can be formed, for example, by printing, plating, or placing the one or more bumps 520 on the one or more interconnect layers 106 of the semiconductor substrate 102. The one or more bumps 520 can be reflowed to form a circular shape, but is not limited to the circular shape. In other embodiments, the one or more bumps 520 can have other shapes such as a planar shape. The one or more bumps 520 can be formed using any suitable electrically conductive material such as, for example, lead, gold, tin, copper, or lead-free materials, or combinations thereof.

The one or more package interconnect structures can include other types of structures than the one or more bumps 520 depicted in FIG. 5A. For example, the one or more package interconnect structures can include solder balls (e.g., the solder balls 112 of FIG. 1) in other embodiments.

Referring to FIG. 5B, a package assembly 500B is depicted subsequent to depositing a molding compound 316 to substantially fill a region between the one or more semiconductor dies 108 and the semiconductor substrate 102. Filling this region with molding compound 316 may save cost and process steps associated with fabrication of the semiconductor substrate 102. Generally, underfill material (e.g., the underfill material 314 of FIG. 3C) is more costly than the molding compound 316.

The molding compound 316 is further deposited to substantially encapsulate the one or more semiconductor dies 108. In some embodiments, the molding compound 316 is deposited to substantially cover a surface on the first side A1 of the semiconductor substrate 102, which can be in either wafer form or singulated form. When the semiconductor substrate 102 is in wafer form, the molding compound 316 can be deposited to overmold an entire surface of the wafer corresponding with the first side A1 of the semiconductor substrate 102. The deposited molding compound 316 can be further divided into smaller blocks or regions for stress/warpage control. For example, portions of the molding compound 316 can be patterned using well-known etch and/or lithography processes or otherwise removed at peripheral edges of each semiconductor substrate unit on the wafer.

Referring to FIG. 5C, a package assembly 500C is depicted subsequent to forming one or more openings 526 in the molding compound 316. According to various embodiments, the one or more openings 526 are formed to expose the one or more package interconnect structures (e.g., the one or more bumps 520). The one or more openings 526 can be formed using a laser ablation or etching process. In these embodiments, the one or more package interconnect structures provide an etch stop or laser stop material during formation of the one or more openings 526.

Referring to FIG. 5D, a package assembly 500D is depicted subsequent to depositing an electrically conductive material (e.g., one or more solder balls 112) to substantially fill the one or more openings (e.g., the one or more openings 526 of FIG. 5C). In the depicted embodiment, one or more solder balls 112 are electrically coupled to the one or more bumps 520, which are electrically coupled to the one or more interconnect layers 106. The one or more solder balls 112 can, for example, be placed and reflowed to provide package interconnect structures for the package assembly 500D. That is, the package interconnect structures can include the one or more solder balls 112 and the one or more bumps 520, coupled as shown.

In other embodiments, the one or more solder balls 112 are formed directly on the one or more interconnect layers 106. That is, in some embodiments, the one or more bumps 520 are not be formed at all and the one or more solder balls 112 are directly bonded to the one or more interconnect layers 106 through the one or more openings.

When the one or more bumps 520 are used in conjunction with the one or more solder balls 112, as depicted, the one or more solder balls 112 can be smaller than solder balls that are used in a package assembly that does not use the one or more bumps 520. The additional height provided by the one or more bumps 520 facilitates using a smaller size for the one or more solder balls 112 because less solder ball material is needed to fill the one or more openings.

The one or more solder balls 112 can include multiple rows of solder balls configured to further route the electrical signals of the one or more semiconductor dies 108. The package interconnect structures can include other types of structures. For example, in some embodiments, one or more post structures are formed in the one or more openings to route the electrical signals of the one or more semiconductor dies 108.

In some embodiments, the package interconnect structures (e.g., the one or more solder balls 112) are attached to a printed circuit board (e.g., the printed circuit board 150 of FIG. 1). According to various embodiments, the package assembly 500D is a final package assembly.

In some embodiments, the semiconductor substrate 102 is in wafer form and a backside of the wafer (e.g., the second side A2 of the semiconductor substrate 102) is thinned to provide a smaller package assembly. Material can be removed from the backside of the wafer using, for example, well-known mechanical and/or chemical wafer-thinning processes such as grinding or etching.

Referring to FIG. 5E, a package assembly 500E is depicted subsequent to forming a molding compound 316 to substantially cover the second side A2 of the semiconductor substrate 102. The molding compound 316 disposed on the second side A2 can be used, for example, to counterbalance stress associated with the molding compound 316 disposed on the first side A1 of the semiconductor substrate 102 and, thus, reduce stress and/or warpage for the package assembly 500E. In some embodiments, the molding compound 316 is deposited on the second side A2 of the semiconductor substrate 102 when the semiconductor substrate 102 is in wafer form, prior to singulation. In some embodiments, the package assembly 500E is a final package assembly.

Referring to FIG. 5F, a package assembly 500F is depicted to show that, in some embodiments, the molding compound 316 is formed on the first side A1 of the semiconductor substrate 102 to have a surface that is substantially coplanar with or lower than an inactive side of the one or more semiconductor dies 108. In an embodiment, the package assembly 500F is formed by removing material of the molding compound 316 of the package assembly 500B of FIG. 5B to expose the one or more semiconductor dies 108. The material can be removed, for example, by a polishing process. In another embodiment, the molding compound 316 of the package assembly 500F is formed by using a mold that is configured to provide a surface of the molding compound 316 that is substantially coplanar with or lower than the inactive side of the one or more semiconductor dies 108. In some embodiments, the package assembly 500F is a final package assembly.

Referring to FIG. 5G, a package assembly 500G is depicted subsequent to the formation of one or more thermal dissipation structures (e.g., solder balls 518) on an inactive side of the one or more semiconductor dies 108, as shown. The one or more thermal dissipation structures generally comprise a thermally conductive material such as, for example, metal (e.g., solder) to provide a thermal path for heat dissipation. The one or more package interconnect structures (e.g., the one or more solder balls 112) and the one or more thermal dissipation structures (e.g., the solder balls 518) can be sized to have surfaces that are substantially coplanar, as can be seen. For example, the solder balls 112 and the solder balls 518 can be sized to have a surface that substantially lies in the same plane 519 to facilitate connection to a substantially planar surface such as a printed circuit board (e.g., the printed circuit board 150 of FIG. 4B). In some embodiments, the solder balls 112 are larger in size than the solder balls 518, as depicted. The solder balls 112, 518 can be formed such that they have surfaces that do not lie in the same plane 519 in other embodiments.

The one or more solder balls 518 can be formed, for example, by forming one or more openings in the molding compound 316 of the package assembly 500B of FIG. 5B or the package assembly 500D of FIG. 5D to expose the inactive side of the one or more semiconductor dies 108. The one or more openings can be formed using a laser ablation or etching process. The inactive side of the one or more semiconductor dies 108 can function as a laser stop or etch stop material. Subsequent to formation of the one or more openings, the one or more solder balls 518 can be deposited to substantially fill the one or more openings over the one or more semiconductor dies 108. In some embodiments, the package assembly 500G is a final package assembly.

FIGS. 6-11 schematically illustrate various package assembly configurations using a semiconductor substrate 102. Although not illustrated, semiconductor substrate 102a may be utilized instead of semiconductor substrate 102.

Referring to FIG. 6, a package assembly 600 is depicted subsequent to formation of a molding compound 316 on the second side A2 of the semiconductor substrate 102. The molding compound 316 can be deposited to substantially cover the second side A2 of the semiconductor substrate 102. The molding compound 316 can be formed to protect or strengthen the semiconductor substrate 102. For example, the molding compound 316 can be formed prior to attaching the one or more semiconductor dies 108 to the semiconductor substrate 102 to protect the semiconductor substrate 102 from chipping or other damage that can occur while handling the semiconductor substrate 102 during package assembly actions described herein. In some embodiments, the molding compound 316 is deposited on the second side A2 of the semiconductor substrate 102 when the semiconductor substrate 102 is in wafer form, prior to singulation.

Referring to FIG. 7, a package assembly 700 is depicted subsequent to attachment of a heat spreader 730 to the second side A2 of the semiconductor substrate 102. The heat spreader 730 includes a structure that facilitates heat removal such as a metal plate. The heat spreader 730 can be thermally coupled to the second side A2 of the semiconductor substrate 102 using a thermally conductive adhesive. The heat spreader 730 can be attached when the semiconductor substrate 102 is in either wafer form or singulated form. In other embodiments, the heat spreader 703 can be formed using deposition processes similar to those used to form the one or more interconnect layers 106.

Referring to FIG. 8, a package assembly 800 is depicted subsequent to removing portions of the semiconductor material from the second side A2 of the semiconductor substrate 102 to increase a surface area for improved heat dissipation. According to various embodiments, one or more recessed regions 832, such as holes or channels, are formed in a surface on the second side A2 of the semiconductor substrate 102. The one or more recessed regions 832 can be formed according to any suitable technique including, for example, an etching process. A profile of the one or more recessed regions 832 can have other shapes than depicted in other embodiments. A thermally conductive layer (not shown) such as a metal layer can be deposited on the surface having the one or more recessed regions 832 to increase thermal dissipation.

Referring to FIG. 9A, a package assembly 900A includes one or more semiconductor dies 108 attached to the semiconductor substrate 102 in a wire-bonding configuration. An inactive side of the one or more semiconductor dies 108 is attached to the first side A1 of the semiconductor substrate 102 using an adhesive 936 and an active side of the one or more semiconductor dies is electrically coupled to the one or more interconnect layers 106 using one or more bonding wires 934. The adhesive can include any suitable die attach material such as an epoxy. The one or more bonding wires 934 generally comprise an electrically conductive material, such as a metal, to route the electrical signals of the one or more semiconductor dies 108. The one or more bonding wires 934 can be formed using, for example, a ball-bonding or wedge-bonding process.

In an embodiment, a bonding wire 934a is formed to electrically couple an active side of a first semiconductor die to an active side of a second semiconductor die, as shown. The one or more bonding wires 934 can further include a bonding wire 934b that electrically couples an active side of a semiconductor die to the one or more interconnect layers 106 disposed between the first semiconductor die and the second semiconductor die. A molding compound 316 is formed to substantially encapsulate the one or more semiconductor dies 108 and the one or more bonding wires 934, as shown.

FIG. 9B illustrates a package assembly 900B that is similar to the package assembly 900A as shown in FIG. 9A. In the package assembly 900B, vias 938, such as through-silicon vias, that are filled with conducting materials are used to provide electrical connections from the semiconductor dies 108 to external components. These vias 938 may be used to provide power and ground connections.

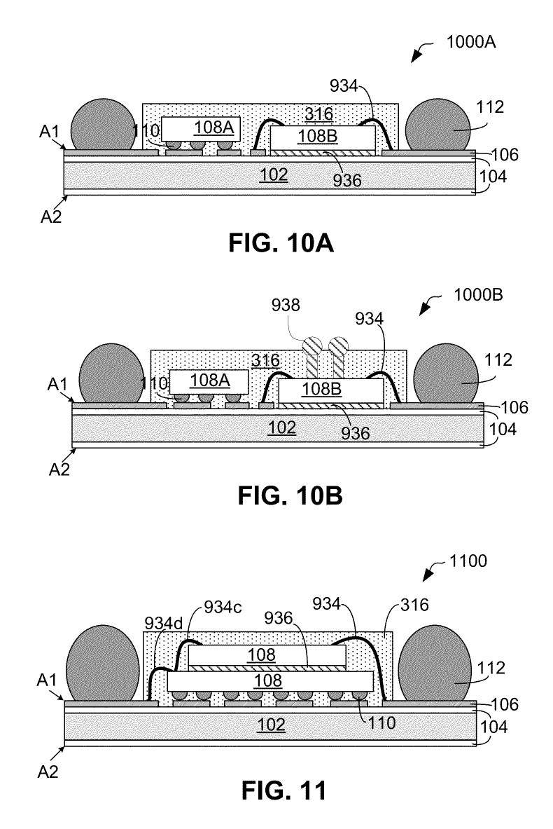

Referring to FIG. 10A, a package assembly 1000A includes one or more semiconductor dies 108A, B attached to the semiconductor substrate 102 in a mixed flip-chip and wire-bonding configuration. For example, a first semiconductor die of the one or more semiconductor dies 108A, B is attached to the semiconductor substrate 102 in a flip-chip configuration using one or more bumps 110 and a second semiconductor die of the one or more semiconductor dies 108A, B is attached to the semiconductor substrate 102 in a wire-bonding configuration using one or more bonding wires 934. A molding compound 316 is formed to substantially encapsulate the one or more semiconductor dies 108A, B and the one or more bonding wires 934, as shown.

FIG. 10B illustrates a package assembly 1000B that is similar to the package assembly 1000A as shown in FIG. 10A. In the package assembly 1000B, vias 938, such as through-silicon vias, that are filled with conducting materials are used to provide electrical connections from the semiconductor die 108B to external components. These vias 938 may be used to provide power and ground connections.

Referring to FIG. 11, a package assembly 1100 includes one or more semiconductor dies 108 attached to the semiconductor substrate 102 in a stacked flip-chip and wire-bonding configuration. A first semiconductor die of the one or more semiconductor dies 108 is attached to the semiconductor substrate 102 in a flip-chip configuration. An active side of the first semiconductor die is electrically coupled to the one or more interconnect layers 106 using one or more bumps 110, as shown. An inactive side of a second semiconductor die of the one or more semiconductor dies 108 is attached to first semiconductor die using an adhesive 936, as shown. In some embodiments, a spacer (not shown) such as dummy silicon can be positioned between the first and second semiconductor dies. An active side of the second semiconductor die is electrically coupled to the one or more interconnect layers 106 using one or more bonding wires 934. In other embodiments, vias (not shown), such as through-silicon vias, that are filled with conducting materials may be used to couple the active side of the second semiconductor die to external components through the molding compound 316. The vias may be used to provide power and ground connections.

In some embodiments, the active side of the second semiconductor die is electrically coupled to the one or more interconnect layers 106 by using a bonding wire 934c to electrically couple the active side of the second semiconductor die to the inactive side of the first semiconductor die and using a bonding wire 934d to electrically couple the first bonding wire 934c to the one or more interconnect layers 106. A molding compound 316 is formed to substantially encapsulate the one or more semiconductor dies 108 and the one or more bonding wires 934, as shown. Although not shown, in other embodiments, a bottom semiconductor die of the one or more semiconductor dies 108 can be coupled to the semiconductor substrate 102 in a wirebonding configuration and a top semiconductor die of the one or more semiconductor dies 108 can be coupled to the bottom semiconductor die in a flip-chip configuration.

Techniques and configurations described in connection with FIGS. 6-11 can be suitably combined with other embodiments described herein. For example, in some embodiments, the techniques and configurations described for the package assemblies of FIGS. 6-8 can be performed on the package assemblies of FIG. 1, FIGS. 3A-3D, FIGS. 4A-4B, FIGS. 5A-5G, or FIGS. 9-11. In some embodiments, the techniques and configurations described for the package assemblies of FIGS. 9-11 can be performed, for example, on the package assemblies of FIG. 1, FIGS. 3A-3D, FIGS. 4A-4B, FIGS. 5A-5G, or FIGS. 6-8. Other suitable combinations of the techniques and configurations described herein can be used in other embodiments.

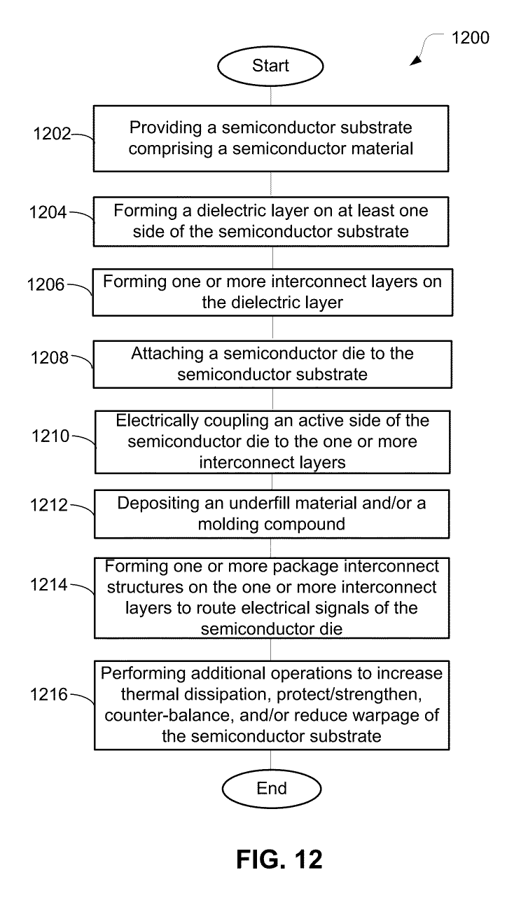

FIG. 12 is a process flow diagram of a method 1200 to fabricate a package assembly (e.g., the package assembly 100 of FIG. 1) using a semiconductor substrate (e.g., the semiconductor substrate 102 of FIG. 1). At 1202, the method 1200 includes providing a semiconductor substrate comprising a semiconductor material. The semiconductor substrate generally has a first side (e.g., the first side A1 of FIG. 2A) and a second side (e.g., the second side A2 of FIG. 2A) that is disposed opposite to the first side. In some embodiments, one or more devices are formed on the first side (e.g., the first side A1 of FIG. 1) of the semiconductor substrate prior to attaching the semiconductor die to the semiconductor substrate. For example, a capacitor (e.g., the capacitor 222 of FIG. 2C) or an ESD protection device (e.g., the ESD protection device 224 of FIG. 2C) can be formed on the first side of the semiconductor substrate. The one or more devices can be formed using techniques described in connection with FIG. 2C and further described in connection with 1204 and 1206 of method 1200.

At 1204, the method 1200 further includes forming a dielectric layer (e.g., the dielectric layer 104 of FIG. 1) on at least one side (e.g., the first side A1) of the semiconductor substrate. The dielectric layer can further be formed on the opposite side (e.g., the second side A2) of the semiconductor substrate in some embodiments.

The dielectric layer 104 can be formed by depositing an electrically insulative material such as, for example, silicon dioxide (SiO₂), silicon nitride (SiN), or silicon oxynitride (SiOₓN_{y}) to substantially cover one or more surfaces of the semiconductor substrate 102, as shown. Other suitable electrically insulative materials can be used in other embodiments.

The dielectric layer 104 can be formed by using a suitable deposition technique including, for example, physical vapor deposition (PVD), chemical vapor deposition (CVD), and/or atomic layer deposition (ALD). Other suitable deposition techniques can be used in other embodiments. The dielectric layer 104 can be used as a dielectric (e.g., gate dielectric) in the formation of the one or more devices (e.g., capacitor 222 or ESD protection device 224 of FIG. 2C) on the semiconductor substrate 102.

At 1206, the method 1200 further includes forming one or more interconnect layers (e.g., the one or more interconnect layers 106 of FIG. 1) on the dielectric layer on the first side of the semiconductor substrate. The one or more interconnect layers can be used to route electrical signals such as, for example, input/output (I/O) signals and/or power/ground signals, to and/or from one or more semiconductor dies (e.g., the one or more semiconductor dies 108 of FIG. 1).

The one or more interconnect layers can be formed by depositing and/or patterning an electrically conductive material such as, for example, a metal (e.g., copper or aluminum) or a doped semiconductor material (e.g., doped polysilicon). Other suitable electrically conductive materials can be used in other embodiments.

The one or more interconnect layers can include a variety of structures to route the electrical signals such as, for example, pads, lands, or traces. A passivation layer comprising an electrically insulative material such as, for example, polyimide can be deposited on the one or more interconnect layers and patterned to provide openings in the passivation layer to facilitate electrical coupling of the one or more semiconductor dies to the one or more interconnect layers.

The one or more interconnect layers can be used as an electrode material in the formation of the one or more devices on the semiconductor substrate. For example, the electrode material can serve as a gate electrode for the one or more devices.

At 1208, the method 1200 further includes attaching a semiconductor die (e.g., the one or more semiconductor dies 108 of FIG. 1) to the semiconductor substrate. As described herein, one or more semiconductor dies can be attached to the first side of the semiconductor substrate in a variety of configurations.

In an embodiment, the semiconductor die is attached to the first side of the semiconductor substrate in a flip-chip configuration (e.g., as shown in the package assembly 100 of FIG. 1). In the flip-chip configuration, the active side of the semiconductor die is generally attached to the first side of the semiconductor substrate using one or more bumps (e.g., the one or more bumps 110 of FIG. 1).

In another embodiment, the semiconductor die is attached to the first side of the semiconductor substrate in a wire-bonding configuration (e.g., as shown in the package assembly 900 of FIG. 9). In the wire-bonding configuration, an inactive side of the semiconductor die is attached to the first side of the semiconductor using an adhesive.

In yet another embodiment, the semiconductor die is attached to the semiconductor substrate in a flip-chip configuration and another semiconductor die is attached to the semiconductor substrate in a wire-bonding configuration (e.g., as shown in the package assembly 1000 of FIG. 10). In still yet another embodiment, an active side of the semiconductor die is attached to the first side of the semiconductor substrate in a flip-chip configuration and an inactive side of another semiconductor die is attached to the semiconductor die using an adhesive (e.g., as shown in the package assembly 1100 of FIG. 11).

At 1210, the method 1200 further includes electrically coupling the active side of the semiconductor die to the one or more interconnect layers. In an embodiment, the active side of the semiconductor die is electrically coupled to the one or more interconnect layers using the one or more bumps. In another embodiment, the active side of the semiconductor die is electrically coupled to the one or more interconnect layers using one or more bonding wires (e.g., the one or more bonding wires 934 of FIG. 9). Combinations of these techniques can be used in other embodiments.

At 1212, the method 1200 further includes depositing an underfill material (e.g., the underfill material 314 of FIG. 3B) and/or a molding compound (e.g., the molding compound 316 of FIGS. 3C, 5B, or 9). The underfill material is generally deposited to substantially fill a region between the semiconductor die and the semiconductor substrate. According to various embodiments, the underfill material is deposited in liquid form by a liquid dispensing or injection process. The underfill material can include, for example, an epoxy or other suitable electrically insulative material.

The molding compound is generally deposited to substantially encapsulate the semiconductor die. In a wire-bonding configuration, the molding compound is deposited to substantially encapsulate the one or more bonding wires. According to various embodiments, the molding compound is formed by depositing a resin (e.g., a thermosetting resin) in solid form (e.g., a powder) into a mold and applying heat and/or pressure to fuse the resin. In some embodiments, the molding compound is not the same material as the underfill material.

In a flip-chip configuration, the molding compound can be used in conjunction with the underfill material (e.g., as shown in FIG. 3C). In other embodiments of the flip-chip configuration, the molding compound can be deposited to fill the underfill region. That is, in some embodiments, the underfill material is not used and the molding compound is deposited to substantially fill a region between the semiconductor die and the semiconductor substrate (e.g., as shown in FIG. 5B). In some embodiments, the molding compound is formed to cover only a portion of the first side of the semiconductor substrate (e.g., as shown in FIG. 3C). In other embodiments, the molding compound is formed to substantially cover the entire first side of the semiconductor substrate (e.g., as shown in FIG. 5B).

At 1214, the method 1200 further includes forming one or more package interconnect structures on the one or more interconnect layers to route electrical signals of the semiconductor die to and/or from the semiconductor substrate. In some embodiments, the one or more package interconnect structures include one or more solder balls (e.g., the one or more solder balls 112 of FIGS. 3D or 5D). The one or more solder balls can be formed, for example, by printing, plating, or placing the one or more solder balls on the one or more interconnect layers of the semiconductor substrate. A reflow process can be used to form a connection between the one or more solder balls and the one or more interconnect layers. In some embodiments, the one or more solder balls can be attached or electrically coupled to the one or more interconnect layers through one or more openings (e.g., the one or more openings 526 of FIG. 5C) formed in the molding compound as described herein.

In some embodiments, the one or more package interconnect structures include one or more bumps (e.g., the one or more bumps 520 of FIG. 5A). The one or more bumps can be formed, for example, by printing, plating, or placing the one or more bumps on the one or more interconnect layers of the semiconductor substrate. The one or more bumps can be reflowed to form a circular shape. The one or more bumps can have other shapes such as a planar shape. The one or more bumps can be formed using any suitable electrically conductive material such as, for example, lead, gold, tin, copper, or lead-free materials, or combinations thereof. The one or more package interconnect structures can include combinations of the one or more bumps and the one or more solder balls (e.g., as shown in FIG. 5D). The one or more package interconnect structures can be electrically coupled to a printed circuit board (e.g., the printed circuit board 150 of FIG. 1).

At 1216, the method 1200 further includes performing additional operations to increase thermal dissipation, protect/strengthen, counter-balance, and/or reduce warpage of the semiconductor substrate. In some embodiments, one or more thermal dissipation structures (e.g., the one or more solder balls 418 or 518 of respective FIGS. 4A or 5G) are formed on an inactive side of a semiconductor die to provide a thermal path for heat dissipation away from the semiconductor die, as described herein. The one or more thermal dissipation structures for heat dissipation can formed simultaneously as the one or more package interconnects and can be subsequently attached to a printed circuit board (e.g., the printed circuit board 150 of FIG. 4B) during a surface mount process to couple the one or more package interconnects to the printed circuit board.

In some embodiments, a heat spreader (e.g., the heat spreader 730 of FIG. 7) is thermally coupled to the second side of the substrate. The heat spreader can be attached, for example, by using a thermally conductive compound. In other embodiments, one or more recessed regions (e.g., the one or more recessed regions 832 of FIG. 8) are formed by removing portions of the semiconductor material from the second side of the semiconductor substrate to increase a surface area of the second side. The increased surface area facilitates heat removal away from the second side of the semiconductor substrate.

In an embodiment, a molding compound is formed to substantially cover the second side of the semiconductor substrate (e.g., as shown in FIG. 6). The molding compound can be used to strengthen and/or protect the semiconductor substrate against chipping or other environmental harm. In some embodiments, the molding compound is formed on the second side of the semiconductor substrate to counter-balance and/or prevent warpage associated with a molding compound formed on the first side of the semiconductor substrate (e.g., as shown in FIG. 5E). The actions described in connection with method 1200 can include other suitable embodiments for techniques described elsewhere in this description.

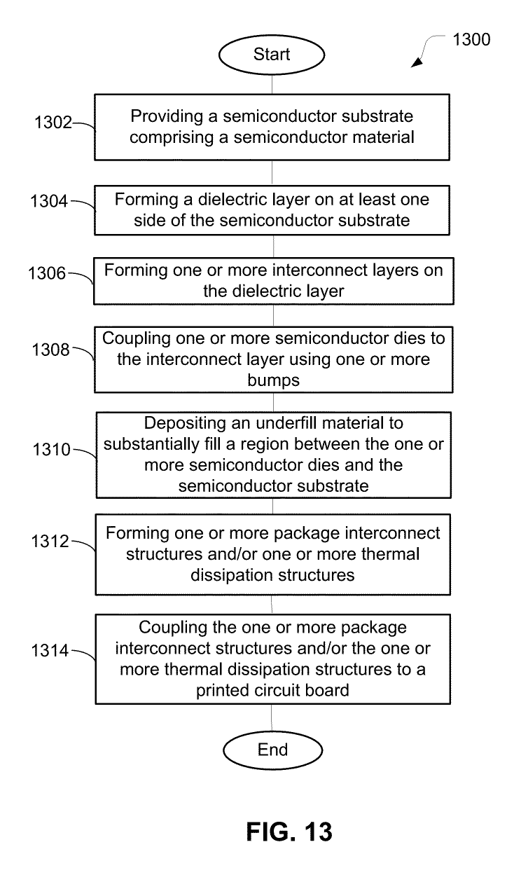

FIG. 13 is a process flow diagram of another method 1300 to fabricate a package assembly (e.g., the package assembly 400B of FIG. 4B) using a semiconductor substrate (e.g., the semiconductor substrate 102 of FIG. 4B). At 1302, 1304, and 1306, the method 1300 respectively includes providing a semiconductor substrate comprising a semiconductor material, forming a dielectric layer on at least one side of the semiconductor substrate, and forming one or more interconnect layers on the dielectric layer, which may comport with embodiments already described in connection with 1202, 1204, and 1206 of method 1200.

At 1308, the method 1300 further includes coupling one or more semiconductor dies (e.g., the semiconductor dies 108 of FIG. 3A) to the interconnect layer using one or more bumps (e.g., the one or more bumps 110 of FIG. 3A). The one or more semiconductor dies can be configured, for example, in a flip-chip configuration where an active side of the semiconductor die is coupled to the semiconductor substrate using the one or more bumps.

At 1310, the method 1300 further includes depositing an underfill material (e.g., the underfill material 314 of FIG. 3B) to substantially fill a region between the semiconductor die and the semiconductor substrate. According to various embodiments, the underfill material is deposited in liquid form by a liquid dispensing or injection process. A molding compound (e.g., the molding compound 316 of FIG. 3C) can also be formed to substantially encapsulate the one or more semiconductor dies. The underfill material and the molding compound generally comport with embodiments described herein.

At 1312, the method 1300 further includes forming one or more package interconnect structures (e.g., the solder balls 112 of FIG. 3D) and/or one or more thermal dissipation structures (e.g., the one or more solder balls 418 of FIG. 4A). The one or more package interconnect structures are electrically coupled to the one or more interconnect layers. In some embodiments, the one or more package interconnect structures are formed on the one or more interconnect layers. The one or more thermal dissipation structures are generally formed on an inactive side of the one or more semiconductor dies to provide a thermal path for heat dissipation. The one or more package interconnect structures and the one or more thermal dissipation structures can be sized to have respective surfaces that are substantially coplanar (e.g., plane 419 of FIG. 4A).

At 1314, the method 1300 further includes coupling the one or more package interconnect structures and/or the one or more thermal dissipation structures to a printed circuit board (e.g., the printed circuit board 150 of FIG. 4B). The printed circuit board can be a motherboard in some embodiments. The one or more package interconnect structures and/or the one or more thermal dissipation structures can be coupled to other electronic devices, such as another package assembly, in other embodiments.

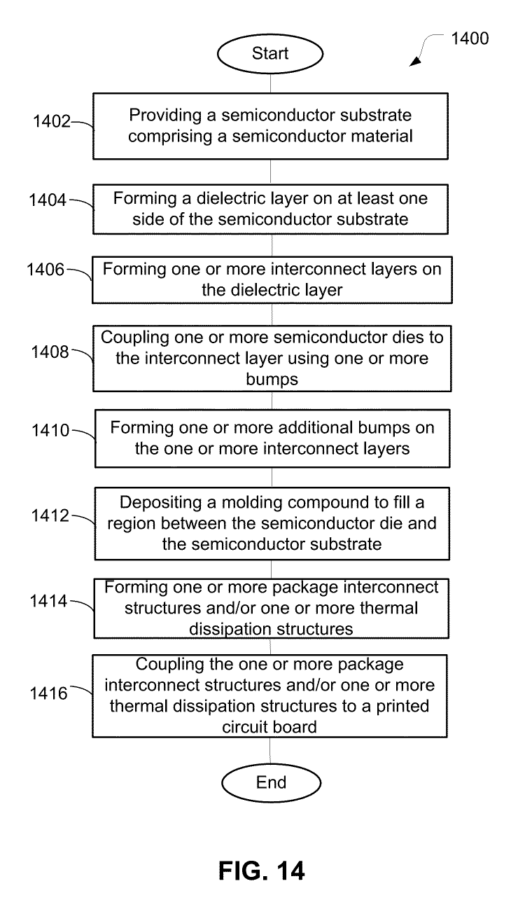

FIG. 14 is a process flow diagram of yet another method 1400 to fabricate a package assembly (e.g., the package assembly 500G of FIG. 5G) using a semiconductor substrate (e.g., the semiconductor substrate 102 of FIG. 5G). At 1402, 1404, and 1406, the method 1400 respectively includes providing a semiconductor substrate comprising a semiconductor material, forming a dielectric layer on at least one side of the semiconductor substrate, and forming one or more interconnect layers on the dielectric layer, which may comport with embodiments already described in connection with 1202, 1204, and 1206 of method 1200.

At 1408, the method 1400 further includes coupling one or more semiconductor dies (e.g., the semiconductor dies 108 of FIG. 5A) to the interconnect layer using one or more bumps (e.g., the one or more bumps 110 of FIG. 5A). The one or more semiconductor dies can be configured, for example, in a flip-chip configuration where an active side of the semiconductor die is coupled to the semiconductor substrate using the one or more bumps.

At 1410, the method 1400 further includes forming one or more additional bumps (e.g., the one or more bumps 520 of FIG. 5A) on the one or more interconnect layers in some embodiments. The one or more additional bumps are generally formed prior to the molding compound being deposited.

At 1412, the method 1400 further includes depositing a molding compound (e.g., the molding compound 316 of FIG. 5B) to fill a region between the semiconductor die and the semiconductor substrate. In some embodiments, the molding compound is deposited to substantially encapsulate the one or more semiconductor dies. A portion of the molding compound can be recessed by well-known mechanical and/or chemical processes to expose a surface of the one or more semiconductor dies.

The molding compound can be formed by depositing a resin of solid form into a mold and subsequently applying heat and/or pressure to fuse the resin. According to various embodiments, the molding compound is deposited when the semiconductor substrate is in wafer form to overmold an entire surface of the wafer. The deposited molding compound can be divided into smaller blocks or regions to reduce stress between the molding compound and the wafer.

In some embodiments where the semiconductor die is coupled to a first side of the semiconductor substrate, a molding compound is formed to substantially cover a second side of the semiconductor substrate, the second side being disposed opposite to the first side of the semiconductor substrate. The molding compound can be used in this manner to reduce stress and/or warpage associated with a molding compound disposed on the first side of the semiconductor substrate.

At 1414, the method 1400 further includes forming one or more package interconnect structures (e.g., the solder balls 112 of FIG. 5G) and/or one or more thermal dissipation structures (e.g., the one or more solder balls 518 of FIG. 5G). The one or more package interconnect structures are electrically coupled to the one or more interconnect layers. In some embodiments, the one or more package interconnect structures are formed on the one or more interconnect layers. In other embodiments where the one or more additional bumps (e.g., the one or more bumps 520 of FIG. 5D) are formed, the one or more package interconnect structures are formed on the one or more additional bumps. For example, one or more openings (e.g., the one or more openings 526 of FIG. 5C) can be formed in the molding compound using an etch or laser process to expose the one or more additional bumps. The one or more additional bumps can function as a laser or etch stop material. Subsequently, the one or more package interconnect structures can be formed on the exposed one or more additional bumps within the one or more openings.

The one or more thermal dissipation structures are generally formed on an inactive side of the one or more semiconductor dies to provide a thermal path for heat dissipation. One or more openings can be formed in the molding compound to expose the inactive side of the one or more semiconductor dies to allow formation of the one or more thermal dissipation structures on the one or more semiconductor dies. The one or more package interconnect structures and the one or more thermal dissipation structures can be sized to have respective surfaces that are substantially coplanar (e.g., plane 519 of FIG. 5G). The semiconductor substrate can be subsequently thinned by grinding or etching processes.

At 1416, the method 1400 further includes coupling the one or more package interconnect structures and/or the one or more thermal dissipation structures to a printed circuit board (e.g., the printed circuit board 150 of FIG. 4B). The printed circuit board can be a motherboard in some embodiments. The one or more package interconnect structures and/or the one or more thermal dissipation structures can be coupled to other electronic devices, such as another package assembly, in other embodiments.

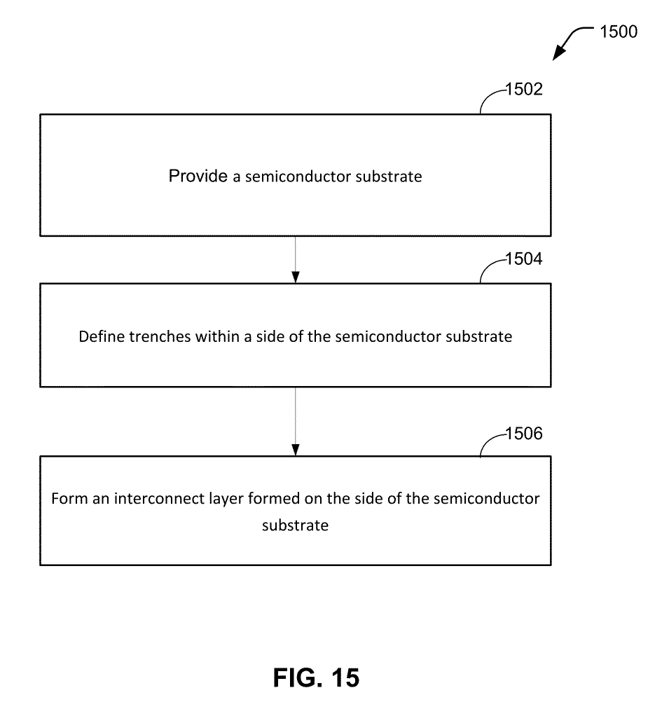

FIG. 15 is a process flow diagram of a method 1500 to fabricate a semiconductor substrate such as the semiconductor substrate 102a of FIGS. 1A and 1B. At 1502, a semiconductor substrate is provided. At 1504, trenches are defined within a side of the semiconductor substrate. At 1506, an interconnect layer is formed on the side of the semiconductor substrate. The interconnect layer is over at least portions of the side of the semiconductor substrate that include the trenches defined within the side of the semiconductor substrate. Each trench is configured to receive a solder ball to provide an interface between the interconnect layer and a substrate to which the apparatus is to be coupled.

The description may use perspective-based descriptions such as up/down, over/under, and/or top/bottom. Such descriptions are merely used to facilitate the discussion and are not intended to restrict the application of embodiments described herein to any particular orientation.

For the purposes of the present disclosure, the phrase “A/B” means A or B. For the purposes of the present disclosure, the phrase “A and/or B” means “(A), (B), or (A and B).” For the purposes of the present disclosure, the phrase “at least one of A, B, and C” means “(A), (B), (C), (A and B), (A and C), (B and C), or (A, B and C).” For the purposes of the present disclosure, the phrase “(A)B” means “(B) or (AB)” that is, A is an optional element.

Various operations are described as multiple discrete operations in turn, in a manner that is most helpful in understanding the claimed subject matter. However, the order of description should not be construed as to imply that these operations are necessarily order dependent. In particular, these operations may not be performed in the order of presentation. Operations described may be performed in a different order than the described embodiment. Various additional operations may be performed and/or described operations may be omitted in additional embodiments.

The description uses the phrases “in an embodiment,” “in embodiments,” or similar language, which may each refer to one or more of the same or different embodiments. Furthermore, the terms “comprising,” “including,” “having,” and the like, as used with respect to embodiments of the present disclosure, are synonymous.

Although certain embodiments have been illustrated and described herein, a wide variety of alternate and/or equivalent embodiments or implementations calculated to achieve the same purposes may be substituted for the embodiments illustrated and described without departing from the scope of the present disclosure. This disclosure is intended to cover any adaptations or variations of the embodiments discussed herein. Therefore, it is manifestly intended that embodiments described herein be limited only by the claims and the equivalents thereof.

What is claimed is:

1. An apparatus configured to be coupled onto a substrate, the apparatus comprising:
a semiconductor substrate, wherein the semiconductor substrate includes a plurality of trenches defined within a side of the semiconductor substrate; and
an interconnect layer over portions of the side of the semiconductor substrate, wherein the portions of the side of the semiconductor substrate include the plurality of trenches defined within the side of the semiconductor substrate,
wherein each trench is configured to respectively receive a solder ball to provide an interface between i) the interconnect layer and ii) the substrate to which the apparatus is to be coupled.

2. The apparatus of claim 1, wherein:
the side is a first side;
the interconnect layer is a first interconnect layer;
the semiconductor substrate further includes a second interconnect layer on a second side of the semiconductor substrate; and
the semiconductor substrate includes through-silicon vias to couple the first interconnect layer and the second interconnect layer.

3. The apparatus of claim 2, further comprising a semiconductor die coupled to the second interconnect layer.

4. The apparatus of claim 3, further comprising multiple dies coupled to the second interconnect layer.

5. The apparatus of claim 1, further comprising a passivation layer over the interconnect layer, wherein the passivation layer includes openings defined therein to expose the interconnect layer over the portions of the side of the semiconductor substrate.

6. The apparatus of claim 1, further comprising the substrate coupled to the apparatus, wherein the substrate is coupled to the apparatus via a plurality of solder balls, and wherein each solder ball of the plurality of solder balls is located within a corresponding trench.

7. The apparatus of claim 6, wherein the substrate comprises one of (i) a printed circuit board or (ii) a package assembly.

8. A method comprising:
providing a semiconductor substrate;
defining a plurality of trenches within a side of the semiconductor substrate; and
forming an interconnect layer on the side of the semiconductor substrate, wherein the interconnect layer is over at least portions of the side of the semiconductor substrate that include the plurality of trenches defined within the side of the semiconductor substrate,
wherein each trench is configured to respectively receive a solder ball to provide an interface between i) the interconnect layer and ii) a substrate to which the semiconductor substrate is to be coupled.

9. The method of claim 8, wherein:
the side is a first side;
the interconnect layer is a first interconnect layer;
the method further comprises forming a second interconnect layer on a second side of the semiconductor substrate; and
the further comprises forming through-silicon vias within the semiconductor substrate to couple the first interconnect layer and the second interconnect layer.

10. The method of claim 9, further comprising attaching a semiconductor die to the second interconnect layer.

11. The method of claim 10, wherein:
the semiconductor die is attached to the second interconnect layer in a flip-chip configuration; and
an active side of the semiconductor die is electrically coupled to the second interconnect layer via one or more solder bumps.

12. The method of claim 10, further comprising attaching multiple dies to the second interconnect layer.

13. The method of claim 12, wherein:
the multiple semiconductor dies are attached to the second interconnect layer in a flip-chip configuration; and
an active side of each semiconductor die of the multiple semiconductor dies is electrically coupled to the second interconnect layer via one or more solder bumps.

14. The method of claim 8, further comprising attaching a semiconductor die to the interconnect layer.

15. The method of claim 14, wherein:
the semiconductor die is attached to the interconnect layer in a flip-chip configuration; and
an active side of the semiconductor die is electrically coupled to the interconnect layer via one or more solder bumps.

16. The method of claim 14, further comprising attaching multiple dies to the interconnect layer.

17. The method of claim 16, wherein:
the multiple semiconductor dies are attached to the interconnect layer in a flip-chip configuration; and
an active side of each semiconductor die of the multiple semiconductor dies is electrically coupled to the interconnect layer via one or more solder bumps.

18. The method of claim 14, wherein:
the semiconductor die is attached to the semiconductor substrate in a wire-bonding configuration;
an inactive side of the semiconductor die is attached to the semiconductor substrate via an adhesive; and
an active side of the semiconductor die is electrically coupled to the interconnect layer via one or more bonding wires.

19. The method of claim 8, further comprising:
forming a passivation layer over the interconnect layer; and
forming openings in the passivation layer to expose the interconnect layer over the portions of the side of the semiconductor substrate.

20. The method of claim 8, further comprising coupling the substrate to the semiconductor substrate, wherein the substrate is coupled to the semiconductor substrate via a plurality of solder balls, and wherein each solder ball of the plurality of solder balls is located within a corresponding trench.

21. The method of claim 20, wherein the substrate comprises one of (i) a printed circuit board or (ii) a package assembly.
